(19) United States
(12) Patent Application Publication
(10) Pub. No.: US 2026/0305492 A1
(43) Pub. Date: Oct. 1, 2026

(54) SEMICONDUCTOR DEVICE AND METHOD FOR MANUFACTURING SEMICONDUCTOR DEVICE

(71) Applicant: Resonac Corporation, Minato-ku, Tokyo (JP)

(72) Inventors: Tsuyoshi TAZAWA, Tokyo (JP); Akiko HAYASHIDE, Tokyo (JP); Shuntaro HIRATA, Tokyo (JP); Koichi CHABANA, Tokyo (JP)

(21) Appl. No.: 19/478,263

(22) PCT Filed: Sep. 9, 2024
(86) PCT No.: PCT/JP2024/032249

§ 371 Date: Oct. 24, 2025

(30) Foreign Application Priority Data
Sep. 22, 2023 (JP) 2023-158828

(51) Int. Cl. H10W 90/20; H10W 74/01; H10W 74/10; H10W 90/10; H10W 90/26

(52) U.S. Cl. CPC H10W 90/291; H10W 74/01; H10W 74/121; H10W 74/141; H10W 90/10; H10W 90/26

(57) ABSTRACT

A semiconductor device includes: a substrate; a stacked chip formed of a plurality of semiconductor chips stacked over a main surface of the substrate; fixed layers disposed between the main surface of the substrate and the stacked chip, and between the plurality of semiconductor chips in the stacked chip; and a fillet extending from the fixed layers to protrude from between the main surface of the substrate and the stacked chip, and from between the plurality of semiconductor chips in the stacked chip, in which the fillet is connected to the main surface of the substrate and an end surface of the stacked chip.

### TECHNICAL FIELD

The present disclosure relates to a semiconductor device and a method for manufacturing a semiconductor device.

### BACKGROUND ART

Conventionally, a method for manufacturing a semiconductor device that includes a plurality of semiconductor chips stacked on a main surface of a substrate using a technology such as through-silicon via (TSV) is known (see, for example, Patent Literatures 1 and 2). In such a method, the plurality of semiconductor chips are stacked on the main surface of the substrate by disposing an underfill material such as a film-like adhesive between the main surface of the substrate and the plurality of semiconductor chips, and between the plurality of semiconductor chips.

### CITATION LIST

### Patent Literature

Patent Literature 1: International Publication WO 2023/074474
Patent Literature 2: U.S. Patent Application Publication No. 2021/210397

### SUMMARY OF INVENTION

### Technical Problem

However, since a film-like adhesive flows during bonding, the adhesive that has flowed from between the main surface of the substrate and the plurality of semiconductor chips and from between the plurality of semiconductor chips protrudes outward, resulting in the formation of a plurality of fillets. The fillet is an adhesive (or a cured product thereof) protruding from between the main surface of the substrate and the semiconductor chip and from between the plurality of semiconductor chips, and projects from between the substrate and the semiconductor chip and from between the plurality of semiconductor chips. Therefore, each fillet is likely to be subjected to external stress, and when each fillet is subjected to external stress, each semiconductor chip may be damaged.

Patent Literature 1 describes a film-like adhesive for semiconductors, as an underfill material, that addresses the issue of reducing the amount of fillet generation and has a first adhesive region having photocurable properties and thermosetting properties, and a second adhesive region having thermosetting properties but not photocurable properties. However, the technique described in Patent Literature 1 has a problem in that the technique lacks versatility because the use of a specific underfill material is necessary. Therefore, it is desirable to suppress damage of the semiconductor chips by another method.

An object of the present disclosure is to provide a semiconductor device and a method for manufacturing a semiconductor device, which are capable of suppressing damage to a semiconductor chip.

### Solution to Problem

A semiconductor device according to the present disclosure includes a substrate, a stacked chip formed of a plurality of semiconductor chips stacked over a main surface of the substrate, fixed layers disposed between the main surface of the substrate and the stacked chip, and between the plurality of semiconductor chips in the stacked chip, and a fillet extending from the fixed layers to protrude from between the main surface of the substrate and the stacked chip, and from between the plurality of semiconductor chips in the stacked chip, in which the fillet is connected to the main surface of the substrate and end surfaces of the stacked chip.

In this semiconductor device, since the fillet extending from the fixed layers to protrude from between the main surface of the substrate and the stacked chip, and from between the plurality of semiconductor chips in the stacked chip is connected to the main surface of the substrate and the end surfaces of the stacked chip, the fillet, the substrate, and the plurality of semiconductor chips are secured to one another. Therefore, even though the fillet receives external stress, displacement of the plurality of semiconductor chips with respect to the substrate is suppressed. Therefore, it is possible to suppress damage to the semiconductor chips.

In the above-described semiconductor device, the fillet may include a chip connection portion extending in a stacking direction of the stacked chip, and a substrate connection portion extending from the chip connection portion in a substrate direction serving as a direction along the main surface of the substrate. Some semiconductor devices include an encapsulation part that encapsulates a main surface of a substrate and a stacked chip. Such an encapsulation part is formed by pouring a molten resin around the main surface of the substrate and the stacked chip. In this case, in a case where large unevenness have been formed on the fillet, the flow of the molten resin may be hindered, and large voids may be generated. However, in this semiconductor device, the fillet has the chip connection portion extending in the stacking direction and the substrate connection portion extending from the chip connection portion in the substrate direction. Therefore, when the encapsulation part is formed, it is possible to suppress obstruction of the flow of the molten resin by the fillet and suppress generation of large voids. In addition, even in a case where the plurality of semiconductor chips are misaligned with each other, or a case where the plurality of semiconductor chips have different sizes from each other, level differences between end surfaces of the plurality of semiconductor chips can be compensated for by the chip connection portion of the fillet. As a result, it is also possible to suppress the obstruction of the flow of the molten resin due to the misalignment or the size difference of the plurality of semiconductor chips. Furthermore, by allowing the chip connection portion of the fillet to extend in the stacking direction of the stacked chips, it is possible to reduce the dimension of the fillet in the direction perpendicular to the stacking direction of the stacked chips. Accordingly, it is possible to achieve space saving and perform high-density mounting.

In the above-described semiconductor device, a surface of the chip connection portion opposite to the stacked chip may be formed in a planar shape. In this semiconductor device, since the surface of the chip connection portion opposite to the stacked chip is formed in a planar shape, it is possible to further suppress generation of large voids when the encapsulation part is formed.

In the above-described semiconductor device, the surface of the substrate connection portion opposite to the main surface of the substrate may be formed in a planar shape. In this semiconductor device, since the surface of the substrate connection portion opposite to the main surface of the substrate is formed in a planar shape, it is possible to further suppress generation of large voids when the encapsulation part is formed.

In the above-described semiconductor device, a maximum thickness of the chip connection portion in the substrate direction is 5 μm or more and 300 μm or less. In this semiconductor device, since the maximum thickness of the chip connection portion in the substrate direction is 5 μm or more and 300 μm or less, level differences between the end surfaces of the stacked chip and the chip connection portion can be reduced. As a result, it is possible to further suppress generation of large voids when the encapsulation part is formed. In addition, the dimension of the fillet in the direction perpendicular to the end surfaces of the stacked chip can be reduced. Accordingly, it is possible to achieve space saving and perform high-density mounting.

In the above-described semiconductor device, the maximum thickness of the substrate connection portion in the stacking direction may be 5 μm or more and 100 μm or less. In this semiconductor device, since the maximum thickness of the substrate connection portion in the stacking direction is 5 μm or more and 100 μm or less, level differences between the main surface of the substrate and the substrate connection portion can be reduced. As a result, it is possible to further suppress generation of large voids when the encapsulation part is formed.

The above-described semiconductor device may include a second stacked chip formed of a plurality of semiconductor chips stacked on a main surface of the substrate, second fixed layers disposed between the main surface of the substrate and the second stacked chip, and between the plurality of semiconductor chips in the second stacked chip, and a second fillet extending from the second fixed layers to protrude from between the main surface of the substrate and the second stacked chip, and from between the plurality of semiconductor chips in the second stacked chip, and the second fillet may be connected to the fillet. In this semiconductor device, since the fillet extending from the fixed layers and the second fillet extending from the second fixed layers are connected to each other, rigidity of the fillet and the second fillet is increased, and displacement of the plurality of semiconductor chips of the stacked chip with respect to the substrate and displacement of the plurality of semiconductor chips of the second stacked chip with respect to the substrate are further suppressed. As a result, damage to the semiconductor chip can be further suppressed.

In the above-described semiconductor device, the second fillet may include a second chip connection portion extending in a stacking direction of the second stacked chip, and a second substrate connection portion extending from the second chip connection portion in a substrate direction serving as a direction along the main surface of the substrate, and the second substrate connection portion of the second fillet may be connected to the substrate connection portion of the fillet. In this semiconductor device, since the substrate connection portion of the fillet and the second substrate connection portion of the second fillet are connected to each other, level differences between the main surface of the substrate and the fillet and the second fillet can be reduced or eliminated. As a result, it is possible to further suppress generation of large voids when the encapsulation part is formed.

The above-described semiconductor device may further include an encapsulation part that encapsulates the main surface of the substrate and the stacked chip. Since this semiconductor device includes the encapsulation part that encapsulates the main surface of the substrate and the stacked chip, it is possible to protect the main surface of the substrate and the stacked chip.

A method for manufacturing a semiconductor device according to the present disclosure includes a stacking step of stacking a plurality of semiconductor chips over a main surface of a substrate by disposing a film-like underfill material between the main surface of the substrate and the plurality of semiconductor chips, and between the plurality of semiconductor chips, in which in the stacking step, the underfill material protrudes from between the substrate and the plurality of semiconductor chips, and from between the plurality of semiconductor chips, and a fillet of the underfill material protruding from between the substrate and the plurality of semiconductor chips, and from between the plurality of semiconductor chips is connected to the main surface of the substrate and end surfaces of a stacked chip formed of the plurality of semiconductor chips.

In this method for manufacturing a semiconductor device, since the fillet of the underfill material protruding from between the substrate and the plurality of semiconductor chips, and from between the plurality of semiconductor chips is connected to the main surface of the substrate and the end surfaces of the stacked chip, the fillet, the substrate, and the plurality of semiconductor chips are secured to one another. Therefore, even though the fillet receives external stress, displacement of the plurality of semiconductor chips with respect to the substrate is suppressed. Therefore, it is possible to suppress damage to the semiconductor chips.

In the above-described method for manufacturing a semiconductor device, the method may further include a cutting step of cutting a part of the fillet. In this method for manufacturing a semiconductor device, since a part of the fillet is cut, the fillet can have any shape.

In the above-described method for manufacturing a semiconductor device, in the cutting step, a part of the fillet may be cut in such a manner that the fillet is formed into a chip connection portion extending in a stacking direction of the stacked chip and a substrate connection portion extending from the chip connection portion in a substrate direction serving as a direction along the main surface of the substrate. In manufacturing the semiconductor device, the main surface of the substrate and the stacked chip may be encapsulated with a resin. Such encapsulation is performed by pouring a molten resin around the main surface of the substrate and the stacked chip. In this case, in a case where large unevenness have been formed on the fillet, the flow of the molten resin may be hindered, and large voids may be generated. However, in this method for manufacturing a semiconductor device, a part of the fillet is cut in such a manner that the fillet is formed into the chip connection portion extending in the stacking direction and the substrate connection portion extending from the chip connection portion in the substrate direction. Therefore, when encapsulation is performed on the main surface of the substrate and the stacked chip with a resin, it is possible to suppress obstruction of the flow of the molten resin by the fillet and suppress generation of large voids. In addition, even in a case where the plurality of semiconductor chips are misaligned with each other, or a case where the plurality of semiconductor chips have different sizes from each other, level differences between end surfaces of the plurality of semiconductor chips can be compensated for by the chip connection portion. As a result, it is also possible to suppress the obstruction of the flow of the molten resin due to the misalignment or the size difference of the plurality of semiconductor chips. Furthermore, by allowing the chip connection portion of the fillet to extend in the stacking direction, it is possible to reduce the dimension of the fillet in the direction perpendicular to the stacking direction of the stacked chips. Accordingly, it is possible to achieve space saving and perform high-density mounting.

In the method for manufacturing a semiconductor device, in the cutting step, a part of the fillet may be cut in such a manner that a surface of the chip connection portion opposite to the stacked chip is formed in a planar shape. In this method for manufacturing a semiconductor device, since a part of the fillet is cut in such a manner that the surface of the chip connection portion opposite to the stacked chip is formed in a planar shape, it is possible to further suppress generation of large voids when the main surface of the substrate and the stacked chip are encapsulated with a resin.

In the method for manufacturing a semiconductor device, in the cutting step, a part of the fillet may be cut in such a manner that a surface of the substrate connection portion opposite to the substrate is formed in a planar shape. In this method for manufacturing a semiconductor device, since a part of the fillet is cut in such a manner that the surface of the substrate connection portion opposite to the substrate is formed in a planar shape, it is possible to further suppress generation of large voids when the main surface of the substrate and the stacked chip are encapsulated with a resin.

The above-described method for manufacturing a semiconductor device may further include an encapsulating step of encapsulating the main surface of the substrate and the stacked chip with a resin. Since in this method for manufacturing a semiconductor device, the main surface of the substrate and the stacked chip are encapsulated with a resin, it is possible to protect the main surface of the substrate and the stacked chip. Advantageous Effects of Invention According to the present disclosure, damage to a semiconductor chip can be suppressed.

### BRIEF DESCRIPTION OF DRAWINGS

FIG. 1 is a schematic cross-sectional view illustrating a semiconductor device according to an embodiment.

FIG. 2 is a schematic cross-sectional view for explaining a method for manufacturing the semiconductor device according to the embodiment.

FIG. 3 is a schematic cross-sectional view for explaining the method for manufacturing the semiconductor device according to the embodiment.

FIG. 4 is a schematic cross-sectional view for explaining the method for manufacturing the semiconductor device according to the embodiment.

FIG. 5 is a schematic cross-sectional view for explaining the method for manufacturing the semiconductor device according to the embodiment.

FIG. 6 is a schematic cross-sectional view for explaining the method for manufacturing the semiconductor device according to the embodiment.

FIG. 7 is a schematic cross-sectional view illustrating a semiconductor device according to a modification.

### DESCRIPTION OF EMBODIMENTS

Hereinafter, the present embodiment is described in detail with reference to the drawings. Hereinafter, the same or corresponding parts are denoted by the same reference numerals, and redundant description will be omitted. In addition, dimensional ratios in the drawings are not limited to the illustrated ratios.

In the present specification, the term “layer” includes a structure having a shape partially formed in addition to a structure having a shape formed on the entire surface when observed as a plan view. In the present specification, the term “process” includes not only an independent process but also a process that cannot be clearly distinguished from other processes as long as an intended action of the process is achieved. In addition, a numerical range using “to” indicates a range including numerical values described before and after “to” as a minimum value and a maximum value.

### Semiconductor Device

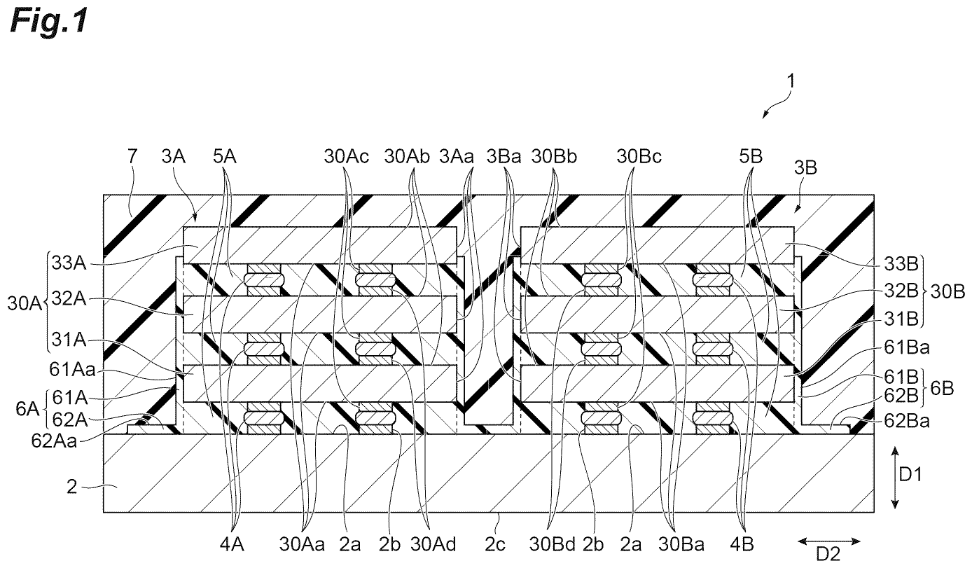

FIG. 1 is a schematic cross-sectional view illustrating a semiconductor device according to an embodiment. As illustrated in FIG. 1, a semiconductor device 1 according to the present embodiment is formed by stacking a first stacked chip 3A and a second stacked chip 3B individually on a main surface 2a of a substrate 2. The semiconductor device 1 is, for example, a semiconductor device (semiconductor package) such as a processor or a memory. The processor may be, for example, a processor unit such as a graphics processing unit (GPU) or a central processing unit (CPU). The memory may be, for example, a memory unit such as a high bandwidth memory (HBM).

The substrate 2 may be, for example, a silicon substrate such as an interposer, an organic substrate, a metal substrate such as a lead frame, or the like. A plurality of electrodes 2b are formed on the main surface 2a of the substrate 2. The main surface 2a is one surface of the substrate 2 on which the plurality of electrodes 2b are formed. Each electrode 2b may be a through-silicon via (TSV) penetrating from the main surface 2a toward a back surface 2c opposite to the main surface 2a.

The first stacked chip 3A includes a plurality of semiconductor chips 30A stacked over the main surface 2a of the substrate 2. The plurality of semiconductor chips 30A may be the same or different from each other. In the present embodiment, the first stacked chip 3A includes the same three semiconductor chips of a first semiconductor chip 31A, a second semiconductor chip 32A, and a third semiconductor chip 33A. In other words, in the present embodiment, the plurality of semiconductor chips 30A include the first semiconductor chip 31A, the second semiconductor chip 32A, and the third semiconductor chip 33A. In the first stacked chip 3A, the first semiconductor chip 31A, the second semiconductor chip 32A, and the third semiconductor chip 33A are stacked in this order over the main surface 2a of the substrate 2.

Each (hereinafter, also simply referred to as the “semiconductor chip 30A”) of the first semiconductor chip 31A, the second semiconductor chip 32A, and the third semiconductor chip 33A has a first main surface 30Aa and a second main surface 30Ab. The first main surface 30Aa is one surface of the semiconductor chip 30A, and the second main surface 30Ab is the other surface of the semiconductor chip 30A opposite to the first main surface 30Aa. The first main surface 30Aa is the one surface of the semiconductor chip 30A over the substrate 2 side, and the second main surface 30Ab is the other surface of the semiconductor chip 30A opposite to the substrate 2. A plurality of electrodes 30Ac are formed on the first main surface 30Aa of the semiconductor chip 30A, and a plurality of electrodes 30Ad are formed on the second main surface 30Ab of the semiconductor chip 30A. Each electrode 30Ad may be a TSV penetrating toward each electrode 30Ac on the opposite side of the electrode 30Ad. A bump 4A is disposed between each of the plurality of electrodes 2b formed on the main surface 2a of the substrate 2 and each of the plurality of electrodes 30Ac formed on the first main surface 30Aa of the first semiconductor chip 31A, and electrical conduction is established between the substrate 2 and the first semiconductor chip 31A via this bump 4A. In addition, a bump 4A is disposed between each of the plurality of electrodes 30Ad formed on the second main surface 30Bb of the first semiconductor chip 31A and each of the plurality of electrodes 30Ac formed on the first main surface 30Ba of the second semiconductor chip 32A, and electrical conduction is established between the first semiconductor chip 31A and the second semiconductor chip 32A via this bump 4A. Furthermore, a bump 4A is disposed between each of the plurality of electrodes 30Ad formed on the second main surface 30Bb of the second semiconductor chip 32A and each of the plurality of electrodes 30Ac formed on the first main surface 30Ba of the third semiconductor chip 33A, and electrical conduction is established between the second semiconductor chip 32A and the third semiconductor chip 33A via this bump 4A.

A first fixed layer 5A is disposed between the main surface 2a of the substrate 2 and the plurality of semiconductor chips 30A, and the first fixed layers 5A are disposed between the plurality of semiconductor chips 30A. In other words, the individual first fixed layers 5A are disposed between the main surface 2a of the substrate 2 and the first main surface 30Aa of the first semiconductor chip 31A, between the second main surface 30Ab of the first semiconductor chip 31A and the first main surface 30Aa of the second semiconductor chip 32A, and between the second main surface 30Ab of the second semiconductor chip 32A and the first main surface 30Aa of the third semiconductor chip 33A. The first fixed layer 5A is one that connects (fixes) the substrate 2 and the plurality of semiconductor chips 30A. The first fixed layers 5A are each a cured product of an underfill material and are disposed between the main surface 2a of the substrate 2 and the plurality of semiconductor chips 30A, and between the plurality of semiconductor chips 30A in manufacturing the semiconductor device 1. Materials of the underfill material and the first fixed layers 5A are not particularly limited, but are, for example, thermosetting resins such as epoxy resins. The first fixed layers 5A are disposed to cover the bump 4A between the main surface 2a of the substrate 2 and each of the plurality of semiconductor chips 30A and the bumps 4A between the plurality of semiconductor chips 30A in order to ensure electrical conduction between the substrate 2 and the plurality of semiconductor chips 30A.

A first fillet 6A extending from the first fixed layers 5A protrudes from between the main surface 2a of the substrate 2 and the plurality of semiconductor chips 30A and from between the plurality of semiconductor chips 30A. In other words, the first fillet 6A extends from the first fixed layers 5A to protrude from between the main surface 2a of the substrate 2 and the plurality of semiconductor chips 30A and from between the plurality of semiconductor chips 30A. The first fillet 6A is a cured product of an underfill material protruding from between the main surface 2a of the substrate 2 and the plurality of semiconductor chips 30A, and from between the plurality of semiconductor chips 30A in manufacturing the semiconductor device 1.

The first fillet 6A is connected to the main surface 2a of the substrate 2 and end surfaces 3Aa of the first stacked chip 3A. The end surfaces 3Aa of the first stacked chip 3A are end surfaces of the plurality of semiconductor chips 30A (first semiconductor chip 31A, second semiconductor chip 32A, and third semiconductor chip 33A). The fact that the first fillet 6A is connected to the main surface 2a of the substrate 2 and the end surfaces 3Aa of the first stacked chip 3A means that the first fillet 6A is fixed to the main surface 2a of the substrate 2 while being fixed to the end surfaces 3Aa of the first stacked chip 3A. In manufacturing the semiconductor device 1, the first fillet 6A is a cured product of an underfill material protruding from between the main surface 2a of the substrate 2 and the plurality of semiconductor chips 30A, and from between the plurality of semiconductor chips 30A, with the underfill material cured in a state of being in contact with the main surface 2a of the substrate 2 and the end surfaces 3Aa of the first stacked chip 3A.

The first fillet 6A has a first chip connection portion 61A extending in a stacking direction D1 of the first stacked chip 3A, and a first substrate connection portion 62A extending in a substrate direction D2 serving as a direction along the main surface 2a of the substrate 2 from the first chip connection portion 61A. In the present embodiment, the first fillet 6A includes (is formed into) the first chip connection portion 61A and the first substrate connection portion 62A. The stacking direction D1 of the first stacked chip 3A is also a direction perpendicular to the main surface 2a of the substrate 2 or a direction perpendicular to the substrate direction D2. Therefore, the first fillet 6A is formed in an L-shaped cross section by the first chip connection portion 61A and the first substrate connection portion 62A.

A surface 61Aa of the first chip connection portion 61A opposite to the first stacked chip 3A is formed in a planar shape. In addition, a surface 62Aa of the first substrate connection portion 62A opposite to the main surface 2a of the substrate 2 is formed in a planar shape. The surface 61Aa of the first chip connection portion 61A is a surface extending in the stacking direction D1 of the first stacked chip 3A. The surface 62Aa of the first substrate connection portion 62A is a surface extending in the substrate direction D2.

The maximum thickness of the first chip connection portion 61A in the substrate direction D2 is, for example, 5 μm or more and 300 μm or less, 10 μm or more and 250 μm or less, or 20 μm or more and 200 μm or less. In addition, the maximum thickness of the first substrate connection portion 62A in the stacking direction D1 of the first stacked chip 3A is, for example, 5 μm or more and 100 μm or less, 8 μm or more and 90 μm or less, or 10 μm or more and 80 μm or less.

The second stacked chip 3B includes a plurality of semiconductor chips 30B stacked over the main surface 2a of the substrate 2. The plurality of semiconductor chips 30B may be the same or different from each other. In the present embodiment, the second stacked chip 3B includes the same three semiconductor chips of a first semiconductor chip 31B, a second semiconductor chip 32B, and a third semiconductor chip 33B. In other words, in the present embodiment, the plurality of semiconductor chips 30B include the first semiconductor chip 31B, the second semiconductor chip 32B, and the third semiconductor chip 33B. In the second stacked chip 3B, the first semiconductor chip 31B, the second semiconductor chip 32B, and the third semiconductor chip 33B are stacked in this order over the main surface 2a of the substrate 2.

Each (hereinafter, also simply referred to as the “semiconductor chip 30B”) of the first semiconductor chip 31B, the second semiconductor chip 32B, and the third semiconductor chip 33B has a first main surface 30Ba and a second main surface 30Bb. The first main surface 30Ba is one surface of the semiconductor chip 30B, and the second main surface 30Bb is the other surface of the semiconductor chip 30B opposite to the first main surface 30Ba. The first main surface 30Ba is the one surface of the semiconductor chip 30B over the substrate 2 side, and the second main surface 30Bb is the other surface of the semiconductor chip 30B opposite to the substrate 2. A plurality of electrodes 30Bc are formed on the first main surface 30Ba of the semiconductor chip 30B, and a plurality of electrodes 30Bd are formed on the second main surface 30Bb of the semiconductor chip 30B. Each electrode 30Bd may be a TSV penetrating toward each electrode 30Bc on the opposite side of the electrode 30Bd. A bump 4B is disposed between each of the plurality of electrodes 2b formed on the main surface 2a of the substrate 2 and each of the plurality of electrodes 30Bc formed on the first main surface 30Ba of the first semiconductor chip 31B, and electrical conduction is established between the substrate 2 and the first semiconductor chip 31B via this bump 4B. In addition, a bump 4B is disposed between each of the plurality of electrodes 30Bd formed on the second main surface 30Bb of the first semiconductor chip 31B and each of the plurality of electrodes 30Bc formed on the first main surface 30Ba of the second semiconductor chip 32B, and electrical conduction is established between the first semiconductor chip 31B and the second semiconductor chip 32B via this bump 4B. Furthermore, a bump 4B is disposed between each of the plurality of electrodes 30Bd formed on the second main surface 30Bb of the second semiconductor chip 32B and each of the plurality of electrodes 30Bc formed on the first main surface 30Ba of the third semiconductor chip 33B, and electrical conduction is established between the second semiconductor chip 32B and the third semiconductor chip 33B via this bump 4B.

A second fixed layer 5B is disposed between the main surface 2a of the substrate 2 and the plurality of semiconductor chips 30B, and the second fixed layers 5B are disposed between the plurality of semiconductor chips 30B. Similarly to the first fixed layer 5A, the second fixed layer 5B is one that connects (fixes) the substrate 2 and the plurality of semiconductor chips 30B.

A second fillet 6B extending from the second fixed layers 5B protrudes from between the main surface 2a of the substrate 2 and the plurality of semiconductor chips 30B and from between the plurality of semiconductor chips 30B. In other words, similarly to the first fillet 6A, the second fillet 6B extends from the second fixed layers 5B to protrude from between the main surface 2a of the substrate 2 and the plurality of semiconductor chips 30B and from between the plurality of semiconductor chips 30B.

Similarly to the first fillet 6A, the second fillet 6B is connected to the main surface 2a of the substrate 2 and end surfaces 3Ba of the second stacked chip 3B. Similarly to the first fillet 6A, the second fillet 6B has a second chip connection portion 61B extending in the stacking direction D1 of the second stacked chip 3B and a second substrate connection portion 62B extending from the second chip connection portion 61B in the substrate direction D2. In the present embodiment, similarly to the first fillet 6A, the second fillet 6B includes (is formed into) the second chip connection portion 61B and the second substrate connection portion 62B.

A surface 61Ba of the second chip connection portion 61B opposite to the second stacked chip 3B is formed in a planar shape. A surface 62Ba of the second substrate connection portion 62B opposite to the main surface 2a of the substrate 2 is formed in a planar shape.

The maximum thickness of the second chip connection portion 61B in the substrate direction D2 can be similar to the maximum thickness of the first chip connection portion 61A in the substrate direction D2. In addition, the maximum thickness of the second substrate connection portion 62B in the stacking direction D1 of the second stacked chip 3B can be similar to the maximum thickness of the first substrate connection portion 62A in the stacking direction D1 of the first stacked chip 3A.

The first stacked chip 3A and the second stacked chip 3B are disposed apart from each other. The second substrate connection portion 62B of the second fillet 6B and the first substrate connection portion 62A of the first fillet 6A are connected to each other between the first stacked chip 3A and the second stacked chip 3B.

The main surface 2a of the substrate 2, the first stacked chip 3A, and the second stacked chip 3B are encapsulated by an encapsulation part 7. In other words, the encapsulation part 7 encapsulates the main surface 2a of the substrate 2, the first stacked chip 3A, and the second stacked chip 3B. The encapsulation part 7 may encapsulate a portion other than the main surface 2a of the substrate 2, or may encapsulate the entire substrate 2. A material of the encapsulation part 7 is not particularly limited, but is, for example, a thermosetting resin such as an epoxy resin.

### Method for Manufacturing Semiconductor Device

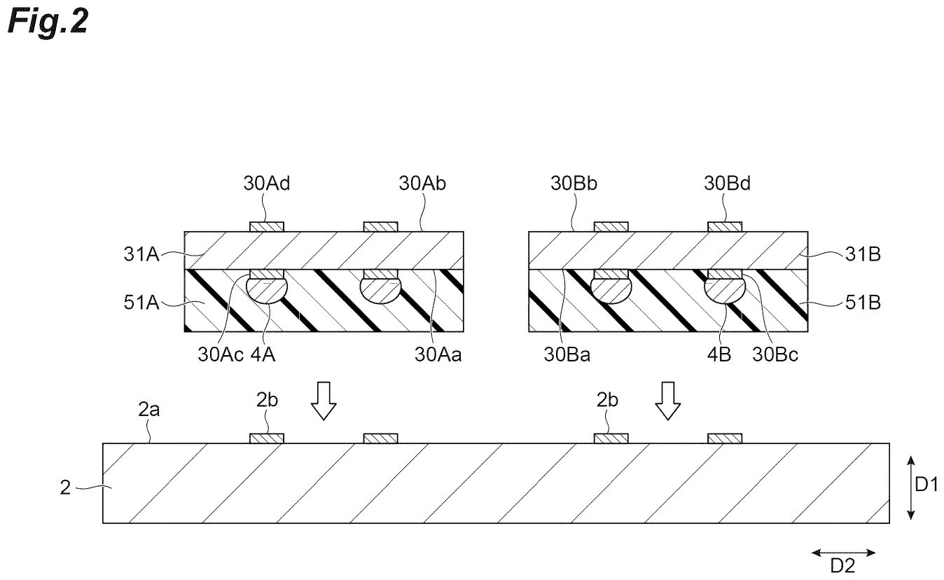

Next, a method for manufacturing a semiconductor device according to the present embodiment will be described with reference to FIGS. 2 to 6. The method for manufacturing a semiconductor device according to the present embodiment is a method for manufacturing the above-described semiconductor device 1. FIGS. 2 to 6 are schematic cross-sectional views for explaining the method for manufacturing the semiconductor device according to the embodiment.

### Stacking Step

In the method for manufacturing a semiconductor device according to the present embodiment, first, a first stacking step is performed. In the first stacking step, the substrate 2, the first semiconductor chip 31A, the second semiconductor chip 32A, the third semiconductor chip 33A, the first semiconductor chip 31B, the second semiconductor chip 32B, the third semiconductor chip 33B, the film-like underfill material 51A, and the film-like underfill material 51B are prepared. The first semiconductor chip 31A, the second semiconductor chip 32A, and the third semiconductor chip 33A are assumed to have the bumps 4A attached to the plurality of electrodes 30Ac formed on the first main surface 30Aa. In addition, the first semiconductor chip 31B, the second semiconductor chip 32B, and the third semiconductor chip 33B are assumed to have the bumps 4B attached to the plurality of electrodes 30Bc formed on the first main surface 30Aa. The underfill material 51A and the material of the underfill material 51A may be the same as the materials of the above-described first fixed layer 5A and second fixed layer 5B

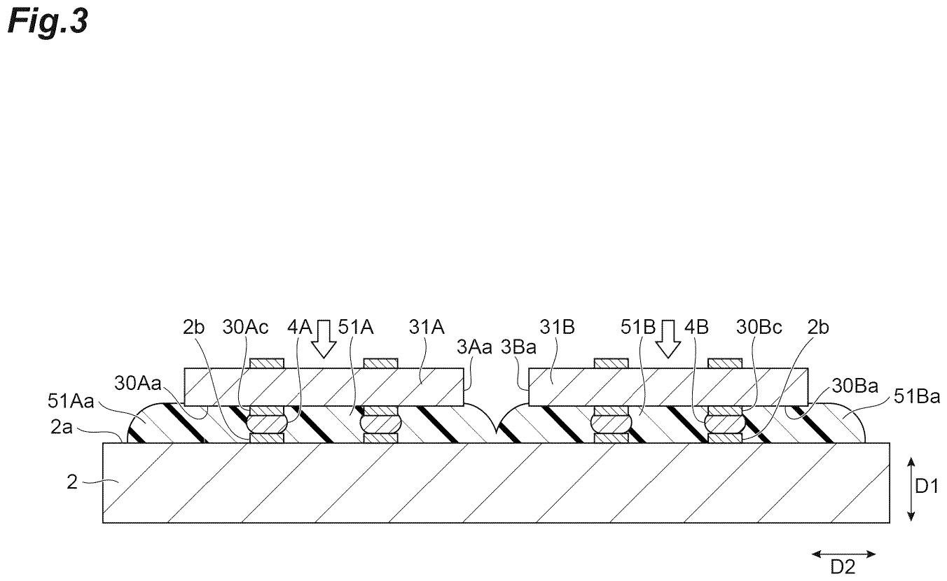

Next, as illustrated in FIGS. 2 and 3, the underfill material 51A is disposed between the main surface 2a of the substrate 2 and the first semiconductor chip 31A, and the first semiconductor chip 31A is stacked over the main surface 2a of the substrate 2. Then, by heating and pressurizing the substrate 2 and the first semiconductor chip 31A, the first semiconductor chip 31A is connected (fixed) onto the main surface 2a of the substrate 2, and electrical conduction is established between the substrate 2 and the first semiconductor chip 31A via the bumps 4A. Similarly, the underfill material 51B is disposed between the main surface 2a of the substrate 2 and the first semiconductor chip 31B, and the first semiconductor chip 31B is stacked over the main surface 2a of the substrate 2. Then, by heating and pressurizing the substrate 2 and the first semiconductor chip 31B, the first semiconductor chip 31B is connected (fixed) onto the main surface 2a of the substrate 2, and electrical conduction is established between the substrate 2 and the first semiconductor chip 31B via the bumps 4B.

In this case, the underfill material 51A disposed between the main surface 2a of the substrate 2 and the first semiconductor chip 31A is heated and pressurized, thereby flowing and protruding from between the substrate 2 and the first semiconductor chip 31A. In addition, the underfill material 51B disposed between the main surface 2a of the substrate 2 and the first semiconductor chip 31B is heated and pressurized, thereby flowing and protruding from between the substrate 2 and the first semiconductor chip 31B. In response, the substrate 2 and the first semiconductor chip 31A are heated and pressurized in such a manner that a fillet 51Aa of the underfill material 51A, which protrudes from between the substrate 2 and the first semiconductor chip 31A, comes into contact with the main surface 2a of the substrate 2 and the end surfaces 3Aa of the first semiconductor chip 31A. In addition, the substrate 2 and the first semiconductor chip 31B are heated and pressurized in such a manner that a fillet 51Ba of the underfill material 51B, which protrudes from between the substrate 2 and the first semiconductor chip 31B, comes into contact with the main surface 2a of the substrate 2 and the end surfaces 3Ba of the first semiconductor chip 31B. In this case, the substrate 2, the first semiconductor chip 31A, and the first semiconductor chip 31B may further be heated and pressurized in such a manner that the fillet 51Aa and the fillet 51Ba come into contact with each other.

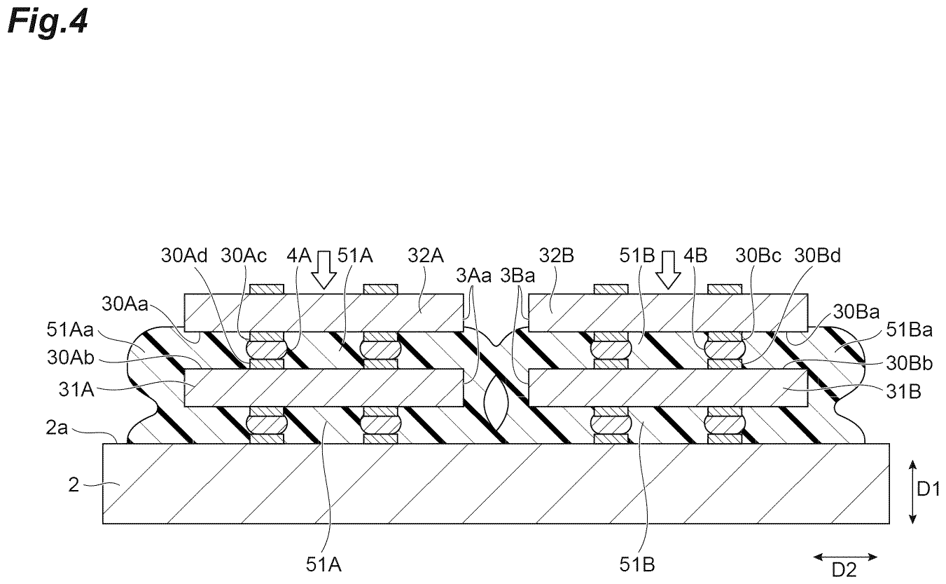

Next, as illustrated in FIG. 4, the underfill material 51A is disposed between the second main surface 30Ab of the first semiconductor chip 31A and the first main surface 30Aa of the second semiconductor chip 32A, and the second semiconductor chip 32A is stacked on the second main surface 30Ab of the first semiconductor chip 31A. Then, by heating and pressurizing the first semiconductor chip 31A and the second semiconductor chip 32A, the second semiconductor chip 32A is connected (fixed) onto the first semiconductor chip 31A, electrical conduction is established between the first semiconductor chip 31A and the second semiconductor chip 32A via the bumps 4A, and the underfill material 51A is allowed to protrude from between the first semiconductor chip 31A and the second semiconductor chip 32A. Similarly, the underfill material 51B is disposed between the second main surface 30Bb of the first semiconductor chip 31B and the first main surface 30Ba of the second semiconductor chip 32B, and the second semiconductor chip 32B is stacked on the second main surface 30Bb of the first semiconductor chip 31B. Then, by heating and pressurizing the first semiconductor chip 31B and the second semiconductor chip 32B, the second semiconductor chip 32B is connected (fixed) onto the first semiconductor chip 31B, electrical conduction is established between the first semiconductor chip 31B and the second semiconductor chip 32B via the bumps 4B, and the underfill material 51B is allowed to protrude from between the first semiconductor chip 31B and the second semiconductor chip 32B.

Furthermore, the first semiconductor chip 31A and the second semiconductor chip 32A are heated and pressurized in such a manner that the fillet 51Aa of the underfill material 51A, which protrudes from between the first semiconductor chip 31A and the second semiconductor chip 32A, comes into contact with the end surfaces 3Aa of the first semiconductor chip 31A and the end surfaces 3Aa of the second semiconductor chip 32A. In addition, the first semiconductor chip 31B and the second semiconductor chip 32B are heated and pressurized in such a manner that the fillet 51Ba of the underfill material 51B, which protrudes from between the first semiconductor chip 31B and the second semiconductor chip 32B, comes into contact with the end surfaces 3Ba of the first semiconductor chip 31B and the end surfaces 3Ba of the second semiconductor chip 32B. In this case, the first semiconductor chip 31A, the second semiconductor chip 32A, the first semiconductor chip 31B, and the second semiconductor chip 32B may further be heated and pressurized in such a manner that the fillet 51Aa and the fillet 51Ba come into contact with each other.

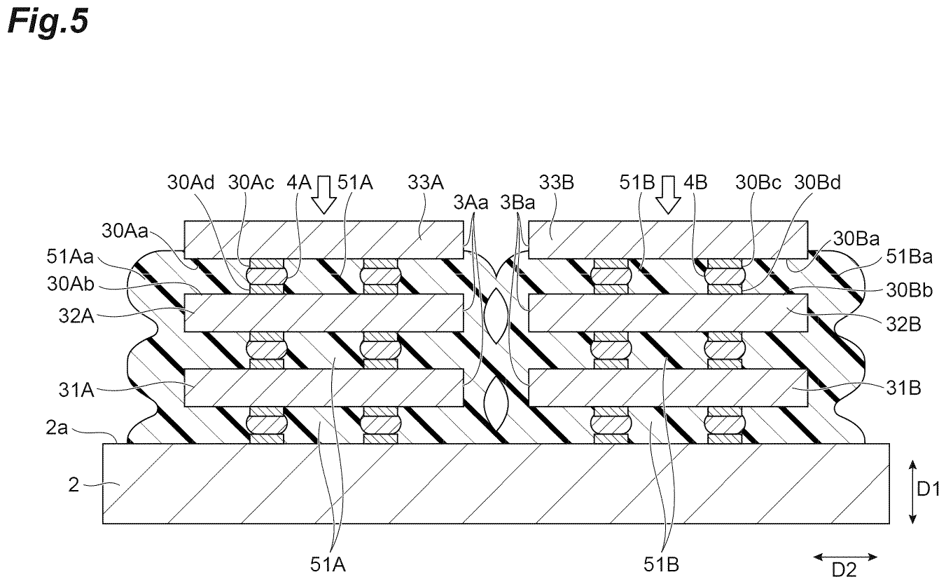

Next, as illustrated in FIG. 5, the underfill material 51A is disposed between the second main surface 30Ab of the second semiconductor chip 32A and the first main surface 30Aa of the third semiconductor chip 33A, and the third semiconductor chip 33A is stacked on the second main surface 30Ab of the second semiconductor chip 32A. Then, by heating and pressing the second semiconductor chip 32A and the third semiconductor chip 33A, the third semiconductor chip 33A is connected (fixed) onto the second semiconductor chip 32A, electrical conduction is established between the second semiconductor chip 32A and the third semiconductor chip 33A via the bumps 4A, and the underfill material 51A is allowed to protrude from between the second semiconductor chip 32A and the third semiconductor chip 33A. Similarly, the underfill material 51B is disposed between the second main surface 30Bb of the second semiconductor chip 32B and the first main surface 30Ba of the third semiconductor chip 33B, and the third semiconductor chip 33B is stacked on the second main surface 30Bb of the second semiconductor chip 32B. Then, by heating and pressurizing the second semiconductor chip 32B and the third semiconductor chip 33B, the third semiconductor chip 33B is connected (fixed) onto the second semiconductor chip 32B, electrical conduction is established between the second semiconductor chip 32B and the third semiconductor chip 33B via the bump 4B, and the underfill material 51B is allowed to protrude from between the second semiconductor chip 32B and the third semiconductor chip 33b.

Furthermore, the second semiconductor chip 32A and the third semiconductor chip 33A are heated and pressurized in such a manner that the fillet 51Aa of the underfill material 51A, which protrudes from between the second semiconductor chip 32A and the third semiconductor chip 33A, comes into contact with the end surfaces 3Aa of the second semiconductor chip 32A and the end surfaces 3Aa of the third semiconductor chip 33A. In addition, the second semiconductor chip 32B and the third semiconductor chip 33B are heated and pressurized in such a manner that the fillet 51Ba of the underfill material 51B, which protrudes from between the second semiconductor chip 32B and the third semiconductor chip 33B, comes into contact with the end surfaces 3Ba of the second semiconductor chip 32B and the end surfaces 3Ba of the third semiconductor chip 33B. Furthermore, the second semiconductor chip 32A, the third semiconductor chip 33A, the second semiconductor chip 32B, and the third semiconductor chip 33B may be heated and pressurized in such a manner that the fillet 51Aa and the fillet 51Ba come into contact with each other.

As a result, the fillet 51Aa of the underfill material 51A, which protrudes from between the substrate 2 and the plurality of semiconductor chips 30A and from between the plurality of semiconductor chips 30A, is brought into a state of being connected to the main surface 2a of the substrate 2 and the end surfaces 3Aa of the first stacked chip 3A formed of the plurality of semiconductor chips 30A. In addition, the fillet 51Ba of the underfill material 51B, which protrudes from between the substrate 2 and the plurality of semiconductor chips 30B, and from between the plurality of semiconductor chips 30B, is brought into a state of being connected to the main surface 2a of the substrate 2 and the end surfaces 3Ba of the second stacked chip 3B formed of the plurality of semiconductor chips 30B. In addition, the fillet 51Aa and the fillet 51Ba are in contact with each other.

In the stacking step, the stacking of the first stacked chip 3A and the stacking of the second stacked chip 3B may be performed at the same timing, at different timings, or partially at the same timing and partially at different timings.

### Cutting Step

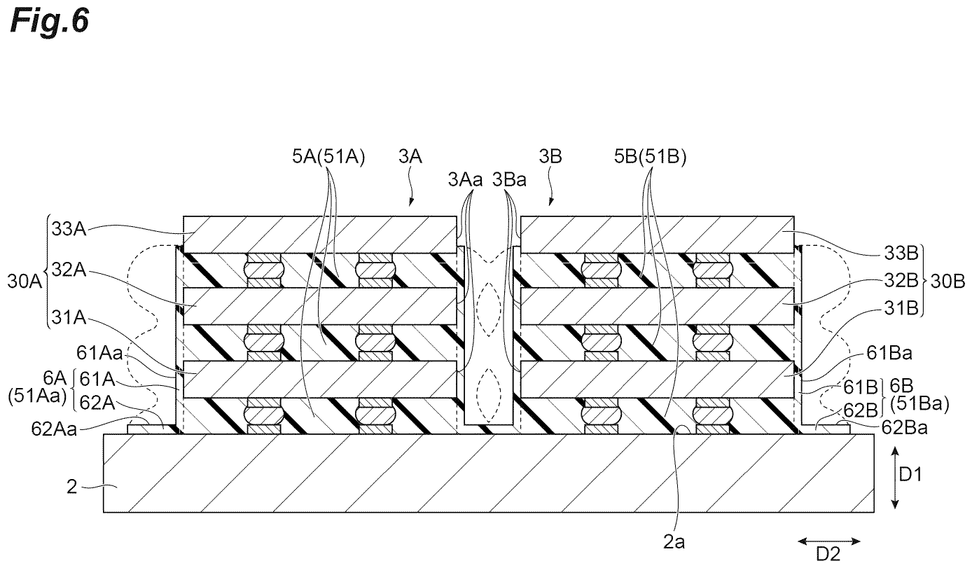

After the stacking step is completed and the fillets 51Aa and 51Ba are cured, a cutting step is performed. As illustrated in FIG. 6, in the cutting step, a part of the fillet 51Aa and a part of the fillet 51Ba are cut. For cutting, for example, a cutting blade such as an electroformed blade can be used.

In the cutting step, by cutting a part of the fillet 51Aa, the first fillet 6A that is a cured product of the fillet 51Aa is formed into the first chip connection portion 61A extending in the stacking direction D1 of the first stacked chip 3A, and the first substrate connection portion 62A extending from the first chip connection portion 61A in the substrate direction D2. In addition, by cutting a part of the fillet 51Ba, the second fillet 6B that is a cured product of the fillet 51Ba is formed into a second chip connection portion 61B extending in the stacking direction D1 of the second stacked chip 3B, and the second substrate connection portion 62B extending from the second chip connection portion 61B in the substrate direction D2. For example, cutting positions in the stacking direction D1 and the substrate direction D2 are adjusted from the side opposite to the substrate 2, with respect to the first stacked chip 3A and the second stacked chip 3B, and a cutting blade performs cutting into the cured product of the fillet 51Aa and the cured product of the fillet 51Ba. As a result, the first fillet 6A can be formed into the first chip connection portion 61A and the first substrate connection portion 62A. In addition, the second fillet 6B can be formed into the second chip connection portion 61B and the second substrate connection portion 62B.

In this case, a part of the first fillet 6A that is a cured product of the fillet 51Aa is cut in such a manner that the surface 61Aa of the first chip connection portion 61A opposite to the first stacked chip 3A is formed in a planar shape, and the surface 62Aa of the first substrate connection portion 62A opposite to the substrate 2 is also formed in a planar shape. In addition, a part of the second fillet 6B that is a cured product of the fillet 51Ba is cut in such a manner that the surface 61Ba of the second chip connection portion 61B opposite to the second stacked chip 3B is formed in a planar shape, and the surface 62Ba of the second substrate connection portion 62B opposite to the substrate 2 is also formed in a planar shape.

### Encapsulating Step

When the cutting step is completed, an encapsulating step is performed. In the encapsulating step, the main surface 2a of the substrate 2, the first stacked chip 3A, and the second stacked chip 3B are encapsulated with a resin. The encapsulating step can be performed, for example, by placing a stacked structure, in which the first stacked chip 3A and the second stacked chip 3B are stacked on the main surface 2a of the substrate 2, into a mold, and encapsulating the main surface 2a of the substrate 2, the first stacked chip 3A, and the second stacked chip 3B with a molten resin. Accordingly, the semiconductor device 1 illustrated in FIG. 1 is obtained. In the encapsulating step, a part of the substrate 2 other than the main surface 2a may be encapsulated with a resin, or the entire substrate 2 may be encapsulated with a resin.

As described above, in the semiconductor device 1 according to the present embodiment, since the first fillet 6A extends from the first fixed layer 5A to protrude from between the main surface 2a of the substrate 2 and the first stacked chip 3A, and from between the plurality of semiconductor chips 30A in the first stacked chip 3A is connected to the main surface 2a of the substrate 2 and the end surfaces 3Aa of the first stacked chip 3A, the first fillet 6A, the substrate 2, and the plurality of semiconductor chips 30A are in a state of being secured to one another. Therefore, even though the first fillet 6A receives external stress, displacement of the plurality of semiconductor chips 30A with respect to the substrate 2 is suppressed. Therefore, it is possible to suppress damage to the semiconductor chips 30A. Furthermore, since at least some of the end surfaces 3Aa of the first stacked chip 3A are covered by the first fillet 6A, it is possible to protect the end surfaces 3Aa of the first stacked chip 3A by the first fillet 6A.

Meanwhile, the encapsulation part 7 is formed by pouring a molten resin around the main surface 2a of the substrate 2, the first stacked chip 3A, and the second stacked chip 3B. In this case, in a case where large unevenness have been formed on the first fillet, the flow of the molten resin may be hindered, and large voids may be generated. However, in the semiconductor device 1, the first fillet 6A includes the first chip connection portion 61A extending in the stacking direction D1 of the first stacked chip 3A, and the second substrate connection portion 62B extending from the first chip connection portion 61A in the substrate direction D2. Therefore, when the encapsulation part 7 is formed, it is possible to suppress obstruction of the flow of the molten resin by the first fillet 6A and suppress generation of large voids. In addition, even in a case where the plurality of semiconductor chips 30A are misaligned with each other, or a case where the plurality of semiconductor chips 30A have different sizes from each other, level differences between the end surfaces 3Aa of the plurality of semiconductor chips 30A can be compensated for by the first chip connection portion 61A of the first fillet 6A. As a result, it is also possible to suppress the obstruction of the flow of the molten resin due to the misalignment or the size difference of the plurality of semiconductor chips 30A. In addition, since the first chip connection portion 61A of the first fillet 6A extends in the stacking direction D1 of the first stacked chips 3A, the dimension of the first fillet 6A in the direction perpendicular to the stacking direction D1 of the first stacked chips 3A can be reduced. Accordingly, it is possible to achieve space saving and perform high-density mounting.

In this semiconductor device 1, since the surface 61Aa of the first chip connection portion 61A opposite to the first stacked chip 3A is formed in a planar shape, it is possible to further suppress the generation of large voids when the encapsulation part 7 is formed.

In this semiconductor device 1, since the surface 62Aa of the first substrate connection portion 62A opposite to the main surface 2a of the substrate 2 is formed in a planar shape, it is possible to further suppress the generation of large voids when the encapsulation part 7 is formed.

In this semiconductor device 1, by setting the maximum thickness of the first chip connection portion 61A in the substrate direction D2 to be 5 μm or more and 300 μm or less, 10 μm or more and 250 μm or less, or 20 μm or more and 200 μm or less, it is possible to reduce level differences between the end surfaces 3Aa of the first stacked chip 3A and the first chip connection portion 61A. As a result, it is possible to further suppress generation of large voids when the encapsulation part 7 is formed. In addition, the dimension of the first fillet 6A in the direction perpendicular to the end surfaces 3Aa of the first stacked chip 3A can be reduced. Accordingly, it is possible to achieve space saving and perform high-density mounting.

In this semiconductor device 1, by setting the maximum thickness of the first substrate connection portion 62A in the stacking direction D1 to be 5 μm or more and 100 μm or less, 8 μm or more and 90 μm or less, or 10 μm or more and 80 μm or less, it is possible to reduce level differences between the main surface 2a of the substrate 2 and the first substrate connection portion 62A. As a result, it is possible to further suppress generation of large voids when the encapsulation part 7 is formed.

In this semiconductor device 1, since the first fillet 6A extending from the first fixed layer 5A and the second fillet 6B extending from the second fixed layer 5B are connected to each other, the rigidity of the first fillet 6A and the second fillet 6B is increased, and displacement of the plurality of semiconductor chips 30A of the first stacked chip 3A with respect to the substrate 2 and displacement of the plurality of semiconductor chips 30B of the second stacked chip 3B with respect to the substrate 2 are further suppressed. As a result, damage to the semiconductor chips 30A and the semiconductor chips 30B can be further suppressed.

In addition, in this semiconductor device 1, since the first substrate connection portion 62A of the first fillet 6A and the second substrate connection portion 62B of the second fillet 6B are connected to each other, level differences between the main surface 2a of the substrate 2 and the first fillet 6A and the second fillet 6B can be reduced or eliminated. As a result, it is possible to further suppress generation of large voids when the encapsulation part 7 is formed.

In addition, since this semiconductor device 1 is provided with the encapsulation part 7 that encapsulates the main surface 2a of the substrate 2, the first stacked chip 3A, and the second stacked chip 3B, it is possible to protect the main surface 2a of the substrate 2, the first stacked chip 3A, and the second stacked chip 3B.

In this method for manufacturing a semiconductor device according to the present embodiment, since the fillet 51Aa of the underfill material 51A protruding from between the substrate 2 and the plurality of semiconductor chips 30A and from between the plurality of semiconductor chips 30A is connected to the main surface 2a of the substrate 2 and the end surfaces 3Aa of the first stacked chip 3A, the first fillet 6A that is a cured product of the fillet 51Aa, the substrate 2, and the plurality of semiconductor chips 30A are secured to one another. Therefore, even though the first fillet 6A receives external stress, displacement of the plurality of semiconductor chips 30A with respect to the substrate 2 is suppressed. Therefore, it is possible to suppress damage to the semiconductor chips 30A. Furthermore, since at least some of the end surfaces 3Aa of the first stacked chip 3A are covered by the first fillet 6A, it is possible to protect the end surfaces 3Aa of the first stacked chip 3A by the first fillet 6A.

In this method for manufacturing a semiconductor device, since a part of the first fillet 6A that is a cured product of the fillet 51Aa is cut, the first fillet 6A can be formed into any shape.

In this method for manufacturing the semiconductor device, a part of the first fillet 6A is cut in such a manner that the first fillet 6A is formed into the first chip connection portion 61A extending in the stacking direction D1 of the first stacked chip 3A, and the first substrate connection portion 62A extending from the first chip connection portion 61A in the substrate direction D2. Therefore, when the encapsulation is performed on the main surface 2a of the substrate 2, the first stacked chip 3A, and the second stacked chip 3B with a resin, it is possible to suppress obstruction of the flow of the molten resin by the first fillet 6A and suppress generation of large voids. In addition, even in a case where the plurality of semiconductor chips 30A are misaligned with each other or the plurality of semiconductor chips 30A are different in size from each other, level differences between the end surfaces 3Aa of the plurality of semiconductor chips 30A can be compensated for by the first chip connection portion 61A. As a result, it is also possible to suppress the obstruction of the flow of the molten resin due to the misalignment or the size difference of the plurality of semiconductor chips 30A. In addition, since the first chip connection portion 61A of the first fillet 6A extends in the stacking direction D1 of the first stacked chips 3A, the dimension of the first fillet 6A in the direction perpendicular to the stacking direction D1 of the first stacked chips 3A can be reduced. Accordingly, it is possible to achieve space saving and perform high-density mounting.

In this method for manufacturing the semiconductor device, since a part of the first fillet 6A is cut in such a manner that the surface 61 Aa of the first chip connection portion 61A opposite to the first stacked chip 3A is formed in a planar shape, it is possible to further suppress the generation of large voids when the main surface 2a of the substrate 2, the first stacked chip 3A, and the second stacked chip 3B are encapsulated with a resin.

In addition, in this method for manufacturing the semiconductor device, since a part of the first fillet 6A is cut in such a manner that the surface 62Aa of the first substrate connection portion 62A opposite to the substrate 2 is formed in a planar shape, it is possible to further suppress the generation of large voids when the main surface 2a of the substrate 2, the first stacked chip 3A, and the second stacked chip 3B are encapsulated with a resin.

In addition, in this method for manufacturing a semiconductor device, since the main surface 2a of the substrate 2, the first stacked chip 3A, and the second stacked chip 3B are encapsulated with a resin, it is possible to protect the main surface 2a of the substrate 2, the first stacked chip 3A, and the second stacked chip 3B.

The present disclosure is not limited to the above-described embodiment, and can be appropriately modified without departing from the gist of the present disclosure.

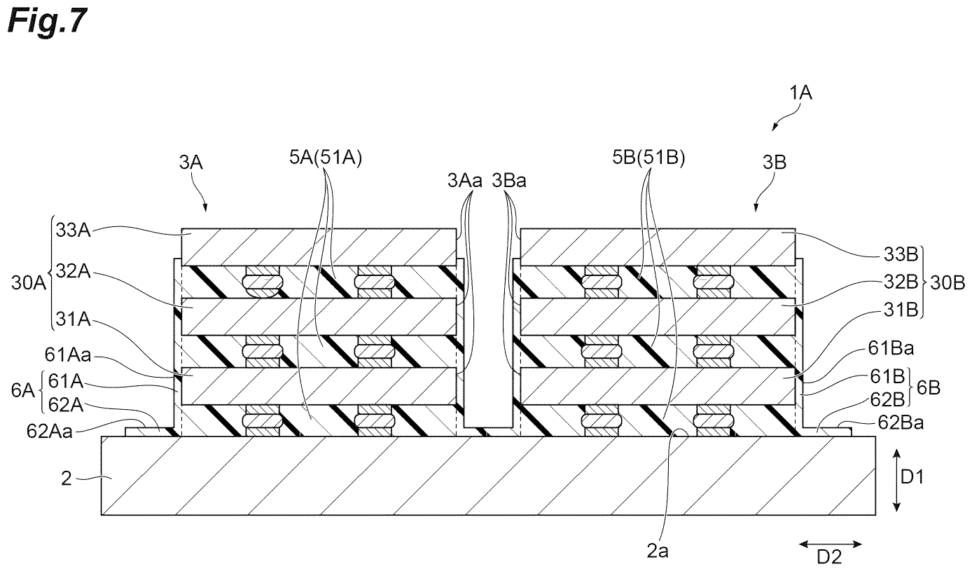

For example, in the above-described embodiment, the semiconductor device has been described as including the encapsulation part, but a semiconductor device 1A of a modification illustrated in FIG. 7 may not include the encapsulation part. In this case, for example, in the method for manufacturing a semiconductor device, the encapsulating step of the above-described embodiment can be omitted.

In the above-described embodiment, the fillet of the semiconductor device has been described as having the chip connection portion extending in the stacking direction of the stacked chip, and the substrate connection portion extending from the chip connection portion in the substrate direction. However, the fillet may have any shape as long as it is connected to the main surface of the substrate and the end surfaces of the stacked chip. In this case, for example, in the method for manufacturing a semiconductor device of the above-described embodiment, the cutting step can be omitted.

In the above-described embodiment, the semiconductor device has been described as having the substrate connection portion of the first fillet and the substrate connection portion of the second fillet connected to each other. However, the first fillet and the second fillet may be separated from each other without being connected. Such a semiconductor device can be manufactured by, for example, heating and pressurizing the second semiconductor chip 32A, the third semiconductor chip 33A, the second semiconductor chip 32B, and the third semiconductor chip 33B in the stacking step of the above-described embodiment in such a manner that the fillet 51 Aa and the fillet 51Ba are not in contact with each other.

In the above-described embodiment, the semiconductor device has been described as the configuration in which two stacked chips of the first stacked chip and the second stacked chip are stacked over the main surface of the substrate. However, the number of stacked chips to be stacked over the main surface of the substrate is not particularly limited, and may be one or may be three or more.

The gist of the present disclosure is as follows [1] to [15].
[1] A semiconductor device including: a substrate; a stacked chip formed of a plurality of semiconductor chips stacked over a main surface of the substrate; fixed layers disposed between the main surface of the substrate and the stacked chip, and between the plurality of semiconductor chips in the stacked chip; and a fillet extending from the fixed layers to protrude from between the main surface of the substrate and the stacked chip, and from between the plurality of semiconductor chips in the stacked chip, in which the fillet is connected to the main surface of the substrate and an end surface of the stacked chip.
[2] The semiconductor device according to [1], in which the fillet includes a chip connection portion extending in a stacking direction of the stacked chip, and a substrate connection portion extending from the chip connection portion in a substrate direction serving as a direction along the main surface of the substrate.
[3] The semiconductor device according to [2], in which a surface of the chip connection portion opposite to the stacked chip is formed in a planar shape.
[4] The semiconductor device according to [2] or [3], in which a surface of the substrate connection portion opposite to the main surface of the substrate is formed in a planar shape.
[5] The semiconductor device according to any one of [2] to [4], in which a maximum thickness of the chip connection portion in the substrate direction is 5 μm or more and 300 μm or less.
[6] The semiconductor device according to any one of [2] to [5], in which a maximum thickness of the substrate connection portion in the stacking direction is 5 μm or more and 100 μm or less.
[7] The semiconductor device according to any one of [1] to [6], further including: a second stacked chip formed of a plurality of semiconductor chips stacked over the main surface of the substrate; second fixed layers disposed between the main surface of the substrate and the second stacked chip, and between the plurality of semiconductor chips in the second stacked chip; and a second fillet extending from the second fixed layers to protrude from between the main surface of the substrate and the second stacked chip, and from between the plurality of semiconductor chips in the second stacked chip, in which the second fillet is connected to the fillet.
[8] The semiconductor device according to [7], in which the second fillet includes a second chip connection portion extending in a stacking direction of the second stacked chip, and a second substrate connection portion extending from the second chip connection portion in a substrate direction serving as a direction along the main surface of the substrate, and the second substrate connection portion of the second fillet is connected to the substrate connection portion of the fillet.
[9] The semiconductor device according to any one of [1] to [8], further including an encapsulation part configured to encapsulate the main surface of the substrate and the stacked chip.
[10] A method for manufacturing a semiconductor device, the method including: a stacking step of stacking a plurality of semiconductor chips over a main surface of a substrate by disposing a film-like underfill material between the main surface of the substrate and the plurality of semiconductor chips, and between the plurality of semiconductor chips, in which in the stacking step, the underfill material protrudes from between the substrate and the plurality of semiconductor chips, and from between the plurality of semiconductor chips, and a fillet of the underfill material protruding from between the substrate and the plurality of semiconductor chips, and from between the plurality of semiconductor chips is connected to the main surface of the substrate and an end surface of a stacked chip formed of the plurality of semiconductor chips.
[11] The method for manufacturing a semiconductor device according to [10], the method further including a cutting step of cutting a part of the fillet.
[12] The method for manufacturing a semiconductor device according to [11], in which in the cutting step, a part of the fillet is cut in such a manner that a chip connection portion extending in a stacking direction of the stacked chip and a substrate connection portion extending from the chip connection portion in a substrate direction serving as a direction along the main surface of the substrate are formed.
[13] The method for manufacturing a semiconductor device according to [12], in which in the cutting step, a part of the fillet is cut in such a manner that a surface of the chip connection portion opposite to the stacked chip is formed in a planar shape.
[14] The method for manufacturing a semiconductor device according to [12] or [13], in which in the cutting step, a part of the fillet is cut in such a manner that a surface of the substrate connection portion opposite to the substrate is formed in a planar shape.
[15] The method for manufacturing a semiconductor device according to any one of [10] to [14], the method further including an encapsulating step of encapsulating the main surface of the substrate and the stacked chip by a resin.

### REFERENCE SIGNS LIST

1 Semiconductor device
2 Substrate
2a Main surface
2b Electrode
2c Back surface
3A First stacked chip
3Aa End surface
3B Second stacked chip
3Ba End surface
4A Bump
4B Bump
5A First fixed layer
5B Second fixed layer
6A First fillet
6B Second fillet
7 Encapsulation part
30A Semiconductor chip
30Aa First main surface
30Ab Second main surface
30Ac Electrode
30Ad Electrode
30B Semiconductor chip
30Ba First main surface
30Bb Second main surface
30Bc Electrode
30Bd Electrode
31A First semiconductor chip
31B First semiconductor chip
32A Second semiconductor chip
32B Second semiconductor chip
33A Third semiconductor chip
33B Third semiconductor chip
51A Underfill material
51Aa Fillet
51B Underfill material
51Ba Fillet
61A First chip connection portion
61Aa Surface
61B Second chip connection portion
61Ba Surface
62A First substrate connection portion
62Aa Surface
62B Second substrate connection portion
62Ba Surface
D1 Stacking direction
D2 Substrate direction

1. A semiconductor device comprising:
a substrate;
a stacked chip formed of a plurality of semiconductor chips stacked over a main surface of the substrate;
fixed layers disposed between the main surface of the substrate and the stacked chip, and between the plurality of semiconductor chips in the stacked chip; and
a fillet extending from the fixed layers to protrude from between the main surface of the substrate and the stacked chip, and from between the plurality of semiconductor chips in the stacked chip,
wherein the fillet is connected to the main surface of the substrate and an end surface of the stacked chip.

2. The semiconductor device according to claim 1,
wherein the fillet includes a chip connection portion extending in a stacking direction of the stacked chip, and a substrate connection portion extending from the chip connection portion in a substrate direction serving as a direction along the main surface of the substrate.

3. The semiconductor device according to claim 2,
wherein a surface of the chip connection portion opposite to the stacked chip is formed in a planar shape.

4. The semiconductor device according to claim 2,
wherein a surface of the substrate connection portion opposite to the main surface of the substrate is formed in a planar shape.

5. The semiconductor device according to claim 2,
wherein a maximum thickness of the chip connection portion in the substrate direction is 5 μm or more and 300 μm or less.

6. The semiconductor device according to claim 2,
wherein a maximum thickness of the substrate connection portion in the stacking direction is 5 μm or more and 100 μm or less.

7. The semiconductor device according to claim 1, further comprising:
a second stacked chip formed of a plurality of semiconductor chips stacked over the main surface of the substrate;
second fixed layers disposed between the main surface of the substrate and the second stacked chip, and between the plurality of semiconductor chips in the second stacked chip; and
a second fillet extending from the second fixed layers to protrude from between the main surface of the substrate and the second stacked chip, and from between the plurality of semiconductor chips in the second stacked chip,
wherein the second fillet is connected to the fillet.

8. The semiconductor device according to claim 7, wherein
the second fillet includes a second chip connection portion extending in a stacking direction of the second stacked chip, and a second substrate connection portion extending from the second chip connection portion in a substrate direction serving as a direction along the main surface of the substrate, and
wherein the second substrate connection portion of the second fillet is connected to the substrate connection portion of the fillet.

9. The semiconductor device according to claim 1, further comprising an encapsulation part configured to encapsulate the main surface of the substrate and the stacked chip.

10. A method for manufacturing a semiconductor device, the method comprising:
stacking a plurality of semiconductor chips over a main surface of a substrate by disposing a film-like underfill material between the main surface of the substrate and the plurality of semiconductor chips, and between the plurality of semiconductor chips,
wherein, in the stacking,
the underfill material protrudes from between the substrate and the plurality of semiconductor chips, and from between the plurality of semiconductor chips, and
a fillet of the underfill material protruding from between the substrate and the plurality of semiconductor chips, and from between the plurality of semiconductor chips is connected to the main surface of the substrate and an end surface of a stacked chip formed of the plurality of semiconductor chips.

11. The method for manufacturing a semiconductor device according to claim 10, the method further comprising cutting a part of the fillet.

12. The method for manufacturing a semiconductor device according to claim 11,
wherein, in the cutting, a part of the fillet is cut in such a manner that the fillet is formed into a chip connection portion extending in a stacking direction of the stacked chip and a substrate connection portion extending from the chip connection portion in a substrate direction serving as a direction along the main surface of the substrate.

13. The method for manufacturing a semiconductor device according to claim 12,
wherein, in the cutting, a part of the fillet is cut in such a manner that a surface of the chip connection portion opposite to the stacked chip is formed in a planar shape.

14. The method for manufacturing a semiconductor device according to claim 12,
wherein, in the cutting step, a part of the fillet is cut in such a manner that a surface of the substrate connection portion opposite to the substrate is formed in a planar shape.

15. The method for manufacturing a semiconductor device according to claim 10, the method further comprising encapsulating the main surface of the substrate and the stacked chip by a resin.
